(19) United States
(12) Patent Application Publication
(10) Pub. No.: US 2013/0075685 A1
(43) Pub. Date: Mar. 28, 2013

(54) METHODS AND APPARATUS FOR INCLUDING AN AIR GAP IN CARBON-BASED MEMORY DEVICES

(71) Applicants: Yubao Li, San Jose, CA (US); Chu-Chen Fu, San Ramon, CA (US)

(72) Inventors: Yubao Li, San Jose, CA (US); Chu-Chen Fu, San Ramon, CA (US)

(21) Appl. No.: 13/241,098

(22) Filed: Sep. 22, 2011

(51) Int. Cl. H01L 47/00; H01L 45/00; B82Y 10/00; B82Y 40/00

(52) U.S. Cl. 257/3; 438/382; 257/E47.001; 257/E45.001; 977/943; 977/842

(57) ABSTRACT

In some aspects, a reversible resistance-switching metal-insulator-metal stack is provided that includes a first conducting layer, a carbon nano-tube (“CNT”) material above the first conducting layer, a second conducting layer above the CNT material, and an air gap between the first conducting layer and the CNT material. Numerous other aspects are provided.

### BACKGROUND

This invention relates to non-volatile memories, and more particularly to methods and apparatus for including an air gap in carbon-based memory devices.

Non-volatile memories formed from reversible resistance switching elements are known. For example, U.S. patent application Ser. No. 11/968,154, filed Dec. 31, 2007, titled “Memory Cell That Employs A Selectively Fabricated Carbon Nano-Tube Reversible Resistance Switching Element And Methods Of Forming The Same” (the “'154 application”), which is hereby incorporated by reference herein in its entirety for all purposes, describes a rewriteable non-volatile memory cell that includes a diode coupled in series with a carbon-based reversible resistivity switching material.

However, fabricating memory devices from carbon-based materials is technically challenging, and improved methods of forming memory devices that employ carbon-based materials are desirable.

### SUMMARY

In a first aspect of the invention, a reversible resistance-switching metal-insulator-metal (“MIM”) stack is provided that includes a first conducting layer, a carbon nano-tube (“CNT”) material above the first conducting layer, a second conducting layer above the CNT material, and an air gap between the first conducting layer and the CNT material.

In a second aspect of the invention, a CNT memory cell is provided that includes a first conductor, a steering element above the first conductor, a first conducting layer above the first conductor, a CNT material above the first conducting layer, a second conducting layer above the CNT material, and an air gap between the first conducting layer and the CNT material.

In a third aspect of the invention, a method of forming a CNT memory cell is provided, the method including forming a first conductor, forming a steering element above the first conductor, forming a first conducting layer above the first conductor, forming a CNT material above the first conducting layer, forming a second conducting layer above the CNT material, and forming an air gap between the first conducting layer and the CNT material.

Other features and aspects of this invention will become more fully apparent from the following detailed description, the appended claims and the accompanying drawings.

### BRIEF DESCRIPTION OF THE DRAWINGS

Features of the present invention can be more clearly understood from the following detailed description considered in conjunction with the following drawings, in which the same reference numerals denote the same elements throughout, and in which:

FIG. 1 is a diagram of an example memory cell in accordance with this invention;

FIG. 2A is a simplified perspective view of an example memory cell in accordance with this invention;

FIG. 2B is a simplified perspective view of a portion of a first example memory level formed from a plurality of the memory cells of FIG. 2A;

FIG. 2C is a simplified perspective view of a portion of a first example three-dimensional memory array in accordance with this invention;

FIG. 2D is a simplified perspective view of a portion of a second example three-dimensional memory array in accordance with this invention;

FIG. 3A is a cross-sectional view of an example embodiment of a memory cell in accordance with this invention;

FIG. 3B is a cross-sectional view of an example embodiment of the memory cell of FIG. 3A;

FIG. 3C is a cross-sectional view of an alternative example embodiment of the memory cell of FIG. 3A;

FIG. 3D is a cross-sectional view of still another alternative example embodiment of the memory cell of FIG. 3A;

FIGS. 4A-4F illustrate cross-sectional views of a portion of a substrate during an example fabrication of a single memory level in accordance with this invention;

FIGS. 5A-5C illustrate cross-sectional views of a portion of a substrate during an alternative example fabrication of a single memory level in accordance with this invention; and

FIGS. 6A-6D illustrate cross-sectional views of a portion of a substrate during another alternative example fabrication of a single memory level in accordance with this invention.

### DETAILED DESCRIPTION

Some CNT materials may be electro-mechanically switchable and exhibit resistivity switching properties that may be used to form microelectronic non-volatile memories. Such films therefore are candidates for integration within a three-dimensional memory array.

Indeed, CNT materials have demonstrated memory switching properties on lab-scale devices with a 100× separation between ON and OFF states and mid-to-high range resistance changes. Such a separation between ON and OFF states renders CNT materials viable candidates for memory cells in which the CNT material is coupled in series with vertical diodes, thin film transistors or other steering elements. For example, a MIM stack formed from a CNT material sandwiched between two metal or otherwise conducting layers (commonly referred to as top and bottom electrodes) may serve as a resistance-switching element for a memory cell.

In particular, a CNT MIM stack may be integrated in series with a diode or transistor to create a read-writable memory device as described, for example, in U.S. patent application Ser. No. 11/968,154, filed Dec. 31, 2007, and titled “Memory Cell That Employs A Selectively Fabricated Carbon Nano-Tube Reversible Resistance-Switching Element And Methods Of Forming The Same,” which is hereby incorporated by reference herein in its entirety for all purposes.

Manufacturing high-yield memory devices that include CNT MIM stacks has proven difficult. A CNT MIM stack is typically fabricated by forming a bottom electrode material, depositing CNT material on the bottom electrode material, and then forming a top electrode material above the CNT material. For example, the CNT material is deposited on the bottom electrode material, such as by spin-coating CNTs directly on the bottom electrode material. In the resulting structure, the CNTs intimately contact the bottom electrode material.

Some researchers have speculated that the intimate contact between the CNT material and the bottom electrode material adversely affects the yield of the resulting memory devices. In particular, CNTs have been known as electro-mechanical switching materials. That is, in response to an applied electric field, the CNT material mechanically switches.

Without wanting to be bound by any particular theory, it is believed that such electromechanical switching of CNTs may be promoted by incorporating free space in which the CNT material may mechanically switch. Further, without wanting to be bound by any particular theory, it is believed that intimate contact between CNTs and bottom electrode material, such as in previously known memory devices, may inhibit electromechanical switching of CNTs, and may impair device yield.

In accordance with embodiments of the invention, a CNT MIM stack may be formed that includes an air gap layer between the bottom electrode and the CNT material. The air gap layer includes a dielectric material having one or more pores, holes or openings to provide one or more air gaps between CNT material and the bottom electrode.

In example embodiments of this invention, the air gap layer may be a porous dielectric film, a spin-coated dielectric nano-structure, a shrunken dielectric layer, or other similar dielectric material having one or more pores, holes or openings.

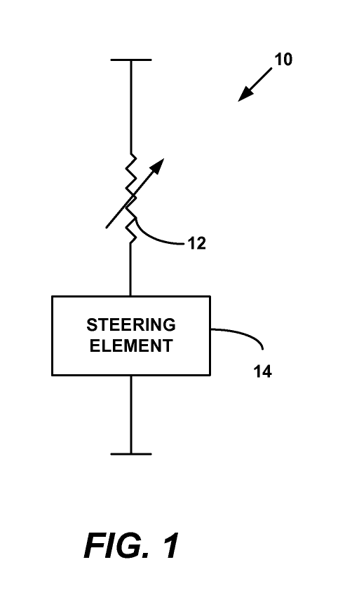

These and other embodiments of the invention are described further below with reference to FIGS. 1-6D.

### Example Inventive Memory Cell

FIG. 1 is a schematic illustration of an example memory cell 10 in accordance with an embodiment of this invention. Memory cell 10 includes a reversible resistance switching element 12 coupled to a steering element 14. Reversible resistance switching element 12 includes a reversible resistivity switching material (not separately shown) having a resistivity that may be reversibly switched between two or more states.

For example, the reversible resistivity switching material of element 12 may be in an initial, low-resistivity state upon fabrication. Upon application of a first voltage and/or current, the material is switchable to a high-resistivity state. Application of a second voltage and/or current may return the reversible resistivity switching material to a low-resistivity state.

Alternatively, reversible resistance switching element 12 may be in an initial, high-resistance state upon fabrication that is reversibly switchable to a low-resistance state upon application of the appropriate voltage(s) and/or current(s). When used in a memory cell, one resistance state may represent a binary “0,” whereas another resistance state may represent a binary “1,” although more than two data/resistance states may be used.

Numerous reversible resistivity switching materials and operation of memory cells employing reversible resistance switching elements are described, for example, in U.S. patent application Ser. No. 11/125,939, filed May 9, 2005 and titled “Rewriteable Memory Cell Comprising A Diode And A Resistance Switching Material” (the “'939 application”), which is hereby incorporated by reference herein in its entirety for all purposes.

Steering element 14 may include a thin film transistor, a diode, a metal-insulator-metal tunneling current device, or another similar steering element that exhibits non-ohmic conduction by selectively limiting the voltage across and/or the current flow through reversible resistance switching element 12. In this manner, memory cell 10 may be used as part of a two or three dimensional memory array and data may be written to and/or read from memory cell 10 without affecting the state of other memory cells in the array.

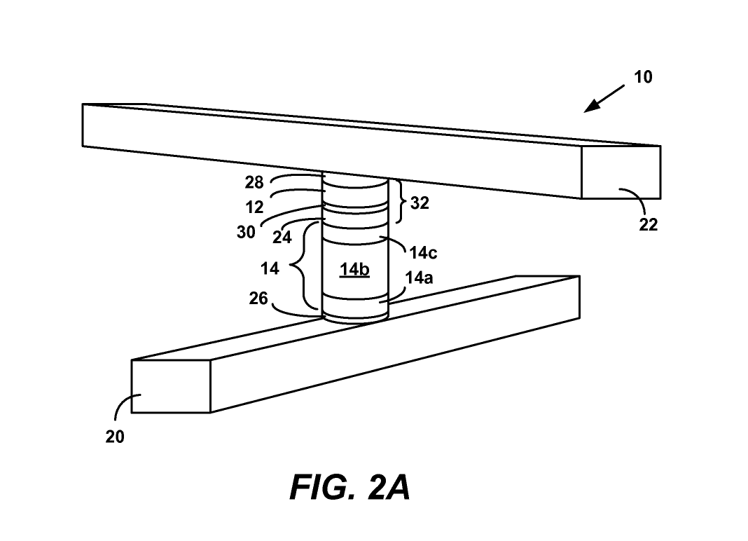

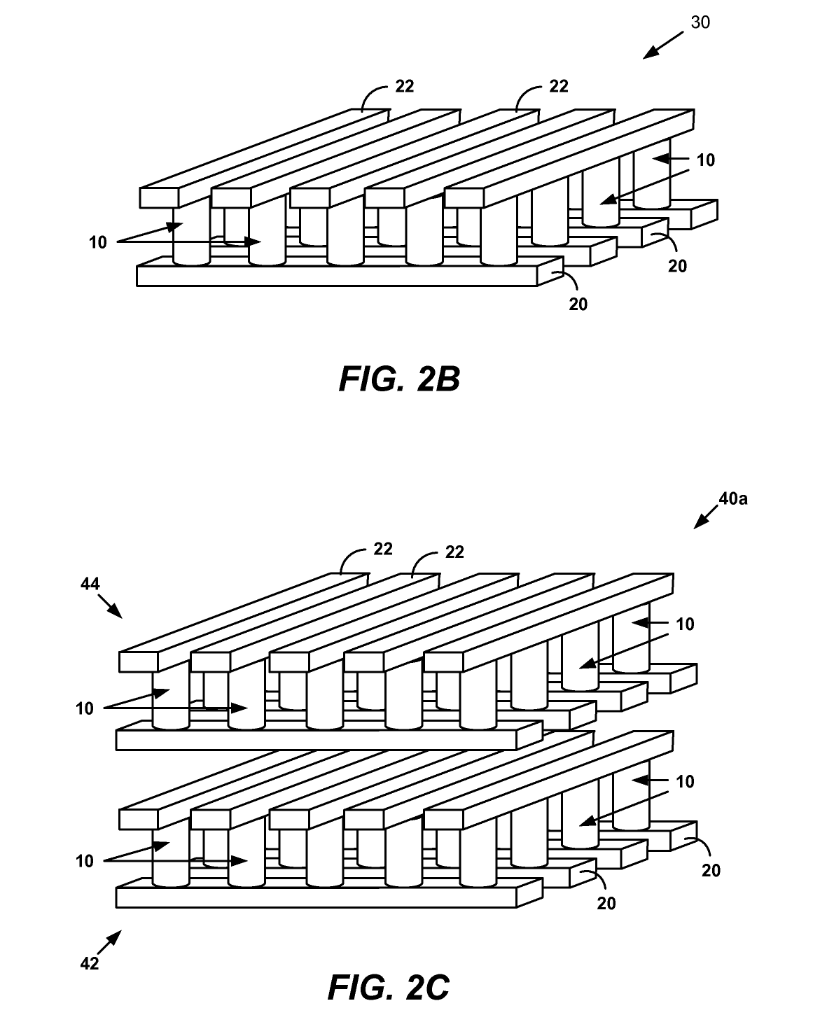

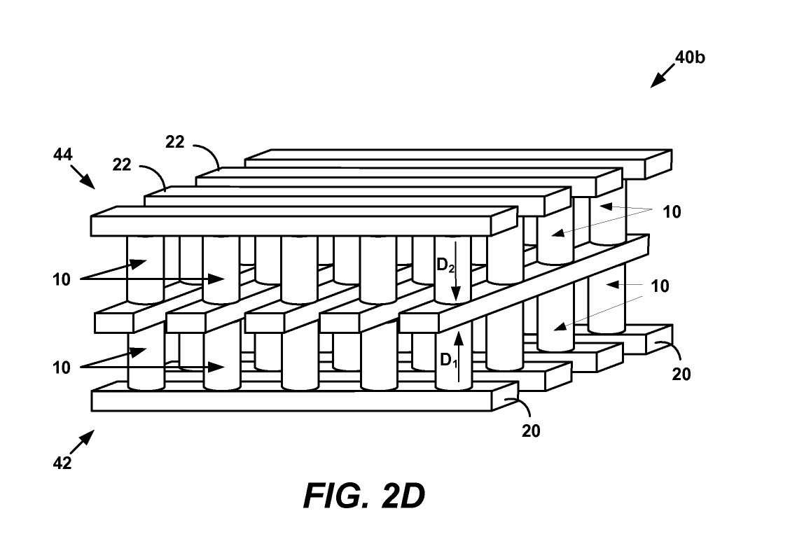

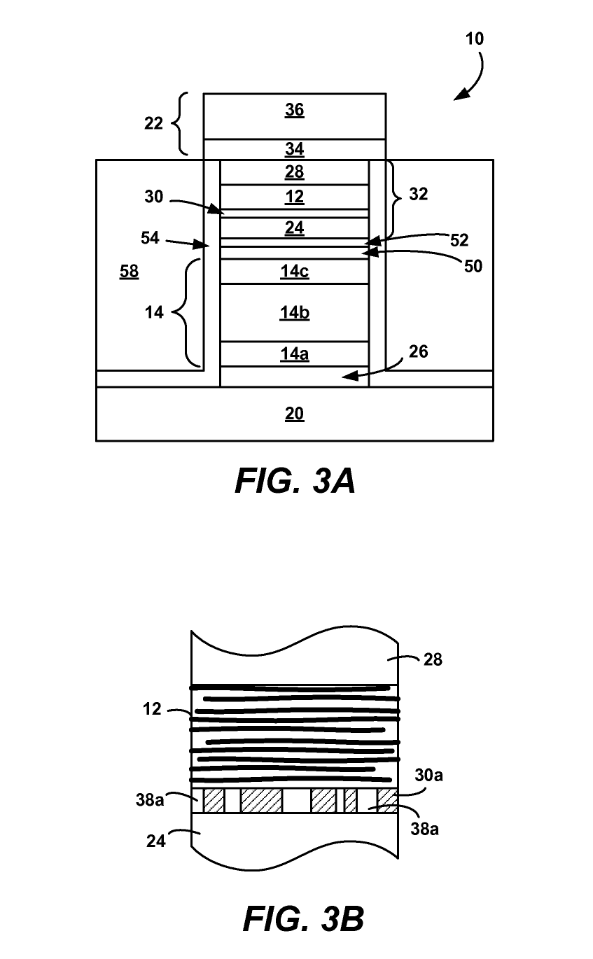

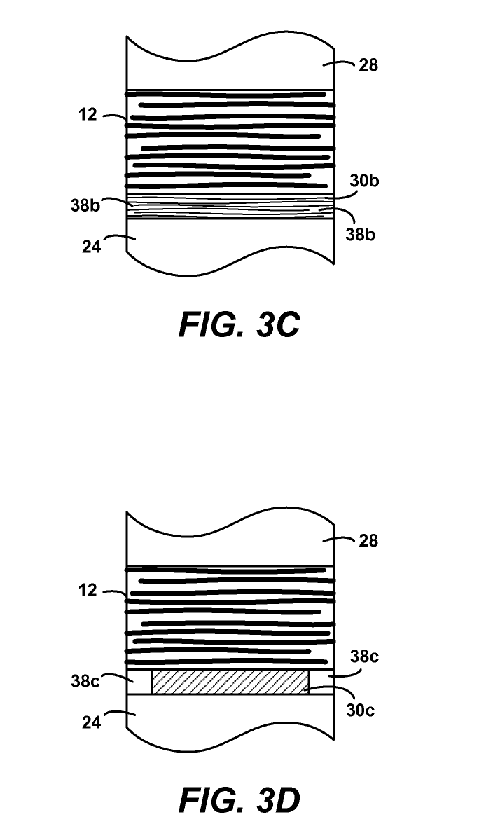

Example embodiments of memory cell 10, reversible resistance switching element 12 and steering element 14 are described below with reference to FIGS. 2A-2D and FIG. 3.

### Example Embodiments of Memory Cells and Memory Arrays

FIG. 2A is a simplified perspective view of an example embodiment of a memory cell 10 in accordance with an embodiment of this invention that includes a steering element 14 and a carbon-based reversible resistance switching element 12. Reversible resistance switching element 12 is coupled in series with steering element 14 between a first conductor 20 and a second conductor 22.

In some embodiments, a first conducting layer 24 may be formed between reversible resistance switching element 12 and steering element 14, a barrier layer 26 may be formed between steering element 14 and first conductor 20, and a second conducting layer 28 may be formed between reversible resistance switching element 12 and second conductor 22. First conducting layer 24, barrier layer 26 and second conducting layer 28 each may include titanium, TiN, tantalum, TaN, tungsten, tungsten nitride (“WN”), molybdenum or another similar material.

In accordance with this invention, an air gap layer 30 is formed between reversible resistance switching element 12 and first conducting layer 24. As described in more detail below, air gap layer 30 includes a dielectric material having one or more pores, holes or openings (not shown) to provide one or more air gaps between reversible resistance switching element 12 and first conducting layer 24.

First conducting layer 24, air gap layer 30, reversible resistance switching element 12, and second conducting layer 28 may form a MIM stack 32 in series with steering element 14, with first conducting layer 24 forming a bottom electrode, and second conducting layer 28 forming a top electrode of MIM stack 32. For simplicity, first conducting layer 24 and second conducting layer 28 will be referred to in the remaining discussion as “bottom electrode 24” and “top electrode 28,” respectively. In some embodiments, reversible resistance switching element 12 and/or MIM stack 32 may be positioned below steering element 14.

As discussed above, steering element 14 may include a thin film transistor, a diode, a metal-insulator-metal tunneling current device, or another similar steering element that exhibits non-ohmic conduction by selectively limiting the voltage across and/or the current flow through reversible resistance switching element 12. In the example of FIG. 2A, steering element 14 is a diode. Accordingly, steering element 14 is sometimes referred to herein as “diode 14.”

Diode 14 may include any suitable diode such as a vertical polycrystalline p-n or p-i-n diode, whether upward pointing with an n-region above a p-region of the diode or downward pointing with a p-region above an n-region of the diode. For example, diode 14 may include a heavily doped n+ polysilicon region 14a, a lightly doped or an intrinsic (unintentionally doped) polysilicon region 14b above the n+ polysilicon region 14a, and a heavily doped p+ polysilicon region 14c above intrinsic region 14b. It will be understood that the locations of the n+ and p+ regions may be reversed. Example embodiments of diode 14 are described below with reference to FIG. 3.

Reversible resistance switching element 12 may include a carbon-based material (not separately shown) having a resistivity that may be reversibly switched between two or more states. For example, reversible resistance switching element 12 may include a CNT material or other similar carbon-based material. For simplicity, reversible resistance switching element 12 will be referred to in the remaining discussion as “CNT element 12.”

First conductor 20 and/or second conductor 22 may include any suitable conductive material such as tungsten, any appropriate metal, heavily doped semiconductor material, a conductive silicide, a conductive silicide-germanide, a conductive germanide, or the like. In the embodiment of FIG. 2A, first and second conductors 20 and 22, respectively, are rail-shaped and extend in different directions (e.g., substantially perpendicular to one another). Other conductor shapes and/or configurations may be used. In some embodiments, barrier layers, adhesion layers, antireflection coatings and/or the like (not shown) may be used with the first conductor 20 and/or second conductor 22 to improve device performance and/or aid in device fabrication.

FIG. 2B is a simplified perspective view of a portion of a first memory level 38 formed from a plurality of memory cells 10, such as memory cell 10 of FIG. 2A. For simplicity, MIM stack 32, diode 14, and barrier layer 26 are not separately shown. Memory level 38 is a “cross-point” array including a plurality of bit lines (second conductors 22) and word lines (first conductors 20) to which multiple memory cells are coupled (as shown). Other memory array configurations may be used, as may multiple levels of memory.

For example, FIG. 2C is a simplified perspective view of a portion of a monolithic three dimensional array 40a that includes a first memory level 42 positioned below a second memory level 44. Memory levels 42 and 44 each include a plurality of memory cells 10 in a cross-point array. Persons of ordinary skill in the art will understand that additional layers (e.g., an interlevel dielectric) may be present between the first and second memory levels 42 and 44, but are not shown in FIG. 2C for simplicity. Other memory array configurations may be used, as may additional levels of memory. In the embodiment of FIG. 2C, all diodes may “point” in the same direction, such as upward or downward depending on whether p-i-n diodes having a p-doped region on the bottom or top of the diodes are employed, simplifying diode fabrication.

In some embodiments, the memory levels may be formed as described in U.S. Pat. No. 6,952,030, titled “High-Density Three-Dimensional Memory Cell” which is hereby incorporated by reference herein in its entirety for all purposes. For instance, the upper conductors of a first memory level may be used as the lower conductors of a second memory level that is positioned above the first memory level as shown in the alternative example three dimensional memory array 40b illustrated in FIG. 2D.

In such embodiments, the diodes on adjacent memory levels preferably point in opposite directions as described in U.S. patent application Ser. No. 11/692,151, filed Mar. 27, 2007, and titled “Large Array Of Upward Pointing P-I-N Diodes Having Large And Uniform Current” (hereinafter “the '151 application”), which is hereby incorporated by reference herein in its entirety for all purposes.

For example, as shown in FIG. 2D, the diodes of the first memory level 42 may be upward pointing diodes as indicated by arrow D1 (e.g., with p regions at the bottom of the diodes), whereas the diodes of the second memory level 44 may be downward pointing diodes as indicated by arrow D2 (e.g., with n regions at the bottom of the diodes), or vice versa.

A monolithic three dimensional memory array is one in which multiple memory levels are formed above a single substrate, such as a wafer, with no intervening substrates. The layers forming one memory level are deposited or grown directly over the layers of an existing level or levels. In contrast, stacked memories have been constructed by forming memory levels on separate substrates and adhering the memory levels atop each other, as in Leedy, U.S. Pat. No. 5,915,167, titled “Three Dimensional Structure Memory.” The substrates may be thinned or removed from the memory levels before bonding, but as the memory levels are initially formed over separate substrates, such memories are not true monolithic three dimensional memory arrays.

In some embodiments, a resistivity of the CNT material used to form CNT element 12 is at least 1×10¹ ohm cm when CNT element 12 is in an ON-state, whereas a resistivity of the CNT material used to form CNT element 12 is at least 1×10³ ohm-cm when CNT element 12 is in an OFF-state. Other resistivities may be used.

FIG. 3A is a cross-sectional view of an example embodiment of memory cell 10 of FIG. 1. In particular, FIG. 3A shows an example memory cell 10 which includes CNT element 12, diode 14, and first and second conductors 20 and 22, respectively. Memory cell 10 also may include bottom electrode 24, barrier layer 26, top electrode 28, air gap layer 30, a silicide layer 50, and a silicide-forming metal layer 52, as well as adhesion layers, antireflective coating layers and/or the like (not shown) which may be used with first and/or second conductors 20 and 22, respectively, to improve device performance and/or facilitate device fabrication. In some embodiments, a sidewall liner 54 may be used to separate selected layers of memory cell 10 from a dielectric layer 58.

In FIG. 3A, diode 14 may be a vertical p-n or p-i-n diode, which may either point upward or downward. In the embodiment of FIG. 2D in which adjacent memory levels share conductors, adjacent memory levels preferably have diodes that point in opposite directions such as downward-pointing p-i-n diodes for a first memory level and upward-pointing p-i-n diodes for an adjacent, second memory level (or vice versa).

In some embodiments, diode 14 may be formed from a polycrystalline semiconductor material such as polysilicon, a polycrystalline silicon-germanium alloy, polygermanium or any other suitable material. For example, diode 14 may include a heavily doped n+ polysilicon region 14a, a lightly doped or an intrinsic (unintentionally doped) polysilicon region 14b above the n+ polysilicon region 14a, and a heavily doped p+ polysilicon region 14c above intrinsic region 14b. It will be understood that the locations of the n+ and p+ regions may be reversed.

In some embodiments, a thin germanium and/or silicon-germanium alloy layer (not shown) may be formed on n+ polysilicon region 14a to prevent and/or reduce dopant migration from n+ polysilicon region 14a into intrinsic region 14b. Use of such a layer is described, for example, in U.S. patent application Ser. No. 11/298,331, filed Dec. 9, 2005 and titled “Deposited Semiconductor Structure To Minimize N-Type Dopant Diffusion And Method Of Making” (hereinafter “the '331 application”), which is hereby incorporated by reference herein in its entirety for all purposes. In some embodiments, a few hundred angstroms or less of silicon-germanium alloy with about 10 at % or more of germanium may be employed.

Barrier layer 26, such as titanium, TiN, tantalum, TaN, tungsten, WN, molybdenum, etc., may be formed between the first conductor 20 and the n+ region 14a (e.g., to prevent and/or reduce migration of metal atoms into the polysilicon regions). In some embodiments, barrier layer 26 may be titanium nitride with a thickness between about 100 to 2000 angstroms, although other materials and/or thicknesses may be used.

If diode 14 is fabricated from deposited silicon (e.g., amorphous or polycrystalline), a silicide layer 50 may be formed on diode 14 to place the deposited silicon in a low resistivity state, as fabricated. Such a low resistivity state allows for easier programming of memory cell 10 as a large voltage is not required to switch the deposited silicon to a low resistivity state.

For example, a silicide-forming metal layer 52 such as titanium or cobalt may be deposited on p+ polysilicon region 14c. During a subsequent anneal step (described below), silicide-forming metal layer 52 and the deposited silicon of diode 14 interact to form silicide layer 50, consuming all or a portion of the silicide-forming metal layer 52. In some embodiments, a nitride layer (not shown) may be formed at a top surface of silicide-forming metal layer 52. For example, if silicide-forming metal layer 52 is titanium, a TiN layer may be formed at a top surface of silicide-forming metal layer 52.

A rapid thermal anneal (“RTA”) step may then be performed to form silicide regions by reaction of silicide-forming metal layer 52 with p+ region 14c. The RTA may be performed at about 540° C. for about 1 minute, and causes silicide-forming metal layer 52 and the deposited silicon of diode 14 to interact to form silicide layer 50, consuming all or a portion of the silicide-forming metal layer 52. An additional, higher temperature anneal (e.g., such as at about 750° C. as described below) may be used to crystallize the diode.

As described in U.S. Pat. No. 7,176,064, titled “Memory Cell Comprising A Semiconductor Junction Diode Crystallized Adjacent To A Silicide,” which is hereby incorporated by reference herein in its entirety for all purposes, silicide-forming materials such as titanium and/or cobalt react with deposited silicon during annealing to form a silicide layer. The lattice spacings of titanium silicide and cobalt silicide are close to that of silicon, and it appears that such silicide layers may serve as “crystallization templates” or “seeds” for adjacent deposited silicon as the deposited silicon crystallizes (e.g., the silicide layer enhances the crystalline structure of the diode 14 during annealing). Lower resistivity silicon thereby is provided. Similar results may be achieved for silicon-germanium alloy and/or germanium diodes.

In embodiments in which a nitride layer was formed at a top surface of silicide-forming metal layer 52, following the RTA step, the nitride layer may be stripped using a wet chemistry. For example, if silicide-forming metal layer 52 includes a TiN top layer, a wet chemistry (e.g., ammonium, peroxide, water in a 1:1:1 ratio) may be used to strip any residual TiN. In some embodiments, the nitride layer formed at a top surface of silicide-forming metal layer 52 may remain, or may not be used at all.

Bottom electrode 24 is formed above metal-forming silicide layer 52. Bottom electrode 24, such as titanium, titanium nitride, tantalum, tantalum nitride, tungsten, tungsten nitride, molybdenum, or other similar material, may be formed between diode 14 and CNT layer 12. In some embodiments, bottom electrode 24 may be titanium nitride with a thickness of between about 10 to 2000 angstroms, more generally between about 20 to 500 angstroms, although other materials and/or thicknesses may be used.

Air gap layer 30 is formed above bottom electrode 24. In accordance with this invention, air gap layer 30 includes a dielectric material having one or more pores, holes or openings to provide one or more air gaps between reversible resistance switching element 12 and bottom electrode 24. Air gap layer 30 may be aluminum oxide (“Al₂O₃”), boron nitride (“BN”), silicon dioxide (“SiO₂”), silicon nitride (“Si₃N₄”), hafnium oxide (“HfO₂”), tantalum oxide (“Ta₂O₅”), tungsten oxide (“WO₃”), molybdenum trioxide (“MoO₃”), zinc oxide (“ZnO”), titanium oxide (“TiO₂”), zirconium oxide (“ZrO₂”) or other similar dielectric material. Air gap layer 30 may have a thickness between about 3 nm to about 5 nm, more generally between about 2 nm to about 10 nm, although other thicknesses may be used. The pores, holes or openings may have a diameter of about 10 nm or less, although other sizes may be used.

In example embodiments of this invention, air gap layer 30 may be a porous dielectric film, a spin-coated dielectric nano-structure, a shrunken dielectric layer, or other similar dielectric material having one or more pores, holes or openings. Each of these will be discussed in turn.

In one example embodiment, air gap layer 30 may be a porous dielectric film. For example, FIG. 3B illustrates a cross-section of a portion of the example memory cell 10 of FIG. 3A. In the illustrated embodiment, air gap layer 30 is a porous dielectric film 30a, such as a porous aluminum oxide film, which may be formed by depositing a layer of aluminum on bottom electrode 24 (e.g., using atomic layer deposition (“ALD”)), and then performing anodic oxidation.

The deposited aluminum layer may have a thickness between about 3 nm to about 5 nm, more generally between about 2 nm to about 10 nm, although other thicknesses may be used. Anodic oxidation may be performed using an aqueous solution of oxalic/sulfuric/phosphoric acid to transform the aluminum layer into a porous aluminum oxide film 30a having pores 38a that have diameters that are less than about 10 nm. Examples of such anodic oxidation processes may be found in Fan Zhang et al., “Nano-porous anodic aluminium oxide membranes with 6-19 nm pore diameters formed by a low-potential anodizing process,” Nanotechnology 18 (2007) 345302, and Jie Gong et al., “Tailoring morphology in free-standing anodic aluminium oxide: control of barrier layer opening down to the sub-10 nm diameter,” Nanoscale 2(5):778-85 (May 2010), each of which is incorporated by reference in its entirety for all purposes.

Alternatively, porous dielectric film 30a may be formed by using physical vapor deposition (“PVD”) to directly deposit a porous dielectric material (e.g., SiO₂, Si₃N₄, Al₂O₃, or other similar dielectric material) between about 3 nm to about 5 nm, more generally between about 2 nm to about 10 nm, on bottom electrode 24. Persons of ordinary skill in the art will understand that other similar techniques may be used to form porous dielectric film 30a.

In another example embodiment, air gap layer 30 may be a spin-coated dielectric nano-structure, including nano-wires, nano-tubes, and/or nano-particles or other similar nano-structures. For example, FIG. 3C illustrates a cross-section of a portion of the example memory cell 10 of FIG. 3A. In the illustrated embodiment, air gap layer 30 includes spin-coated dielectric nano-structures 30b having air gaps 38b between dielectric nano-structures. The layer of spin-coated dielectric structures 30b may have a thickness between about 3 nm to about 5 nm, more generally between about 2 nm to about 10 nm, although other thicknesses may be used.

For example, spin-coated dielectric nano-structures 30b may include single-walled, double-walled, or multi-walled BN nanotubes having diameters of between about 1 nm to about 3 nm, more generally between about 0.5 nm to about 5 nm. Alternatively, spin-coated dielectric nano-structures 30b may include nano-wires fabricated from Al₂O₃, SiO₂, Si₃N₄, or other similar dielectric material, having diameters of between about 2 nm to about 5 nm. Other materials, nano-structures and diameters may be used.

Any of a variety of techniques may be used to form dielectric nano-structures 30b. For example, Rau Arenal et al., “Root-Growth Mechanism for Single-Walled Boron Nitride Nanotubes in Laser Vaporization Technique,” J. Am. Chem. Soc., 129 (51):16183-16189 (2007), which is incorporated by reference herein in its entirety for all purposes, describes a growth mechanism of single-walled BN nanotubes synthesized by laser vaporization.

In addition, Junjie Niu et al., “Tiny SiO₂ nano-wires synthesized on Si (111) wafer,” Physica E: Low-dimensional Systems and Nanostructures, 23(1-2): 1-4, June 2004, which is incorporated by reference herein in its entirety for all purposes, describes synthesis of SiO₂ nano-wires using chemical vapor deposition (“CVD”). Also, Antonio Tricoli et al., “Scalable flame synthesis of SiO₂ nanowires: dynamics of growth,” Nanotechnology 21:465604 (2010), which is incorporated by reference herein in its entirety for all purposes, describes techniques for growing silica nano-wire arrays by scalable flame spray pyrolysis of organometallic solutions (hexamethyldisiloxane or tetraethyl orthosilicate). Other techniques may be used to form dielectric nano-structures 30b.

Any of a variety of techniques may be used to spin-coat dielectric nano-structures 30b on bottom electrode 24. For example, BN nanotubes may be functionalized to make them soluble in a solvent, and then the solubilized BN nanotubes may then be spin-coated on bottom electrode 24. Alternatively, nano-wires (e.g., Al₂O₃, SiO₂, Si₃N₄, or other similar dielectric nano-wires) may be directly dispersed and/or soluble insolvents such as isopropanol, and the solubilized nano-wires may then be spin-coated on bottom electrode 24.

Any of a variety of techniques may be used to functionalize BN nanotubes. For example, Singaravelu Velayudham et al. “Noncovalent Functionalization of Boron Nitride Nanotubes with Poly(p-phenylene-ethynylene)s and Polythiophene,” ACS Appl. Mater. Interfaces, 2(1):104-110 (2010), which is incorporated by reference herein in its entirety for all purposes, describes functionalization of BN nanotubes in organic solvents, such as chloroform, methylene chloride, and tetrahydrofuran. In addition, Shrinwantu Pal et al., “Functionalization and solubilization of BN nanotubes by interaction with Lewis bases,” J. Mater. Chem., 17:450-452 (2007), which is incorporated by reference herein in its entirety for all purposes, describes a technique for dispersing BN nanotubes in a hydrocarbon medium with retention of the nanotube structure. Other similar techniques may be used to functionalize BN nanotubes.

Any of a variety of techniques may be used to solubilize dielectric nano-wires. For example, Ding-Shin Wang et al., “Fabrication Of Large-Area Gallium Arsenide Nanowires Using Silicon Dioxide Nanoparticle Mask,” Journal of Vacuum Science & Technology B: Microelectronics and Nanometer Structures, 27(6):2449-52 (2009), which is incorporated by reference herein in its entirety for all purposes, describes a technique for solubilizing SiO2 nanoparticles. Other similar techniques may be used to solubilize dielectric nano-wires.

In the example embodiment of FIG. 3C, CNT element 12 includes multiple CNTs formed above spin-coated dielectric nano-structures 30b. Alternatively, memory cells in accordance with this invention may include a first layer of CNTs, a layer of spin-coated dielectric nano-structures 30b above the first layer of CNTs, and a second layer of CNTs formed above the spin-coated dielectric nano-structures 30b to form a CNT/dielectric nano-structure/CNT sandwiched stack. In such an embodiment, switching may occur in the air gaps that exist in the dielectric nano-structure between the first and second layers of CNTs.

In another example embodiment, air gap layer 30 may be a shrunken dielectric film. For example, FIG. 3D illustrates a cross-section of a portion of the example memory cell 10 of FIG. 3A. In the illustrated embodiment, air gap layer 30 is a shrunken dielectric film 30c having a peripheral air gap 38c.

Example dielectric film materials include Al₂O₃, BN, SiO₂, Si₃N₄, or other similar dielectric materials. Example deposition techniques include ALD, low-pressure CVD (“LPCVD”) and ion beam sputtering (“IBS”), although other techniques may be used. Alternatively, the top surface of bottom electrode 24 may be oxidized to form an insulating oxide layer. Dielectric film 30c may have a thickness between about 3 nm to about 5 nm, more generally between about 2 nm to about 10 nm, although other thicknesses may be used.

As described in more detail below, after subsequent processing of memory cell 10, an etch (e.g., a wet etch or other similar etch) is performed to undercut dielectric film 30c to form peripheral air gap 38c. The etch may laterally shrink dielectric film 30c between about 3 nm to about 5 nm, although other lateral shrinkage amounts may be used. In the embodiment illustrated in FIG. 3D, peripheral air gap 38c has an o-ring shape. Persons of ordinary skill in the art will understand that peripheral air gap 38c may have other shapes.

Any suitable technique may be used to etch dielectric film 30c. For example, for Al₂O₃ and SiO₂ dielectric films, a hydrofluoric acid etch solution may be used. For Si₃N₄ films, phosphoric acid (“H₃PO₄”) at a temperature between about 150° C. to about 180° C. may be used. Other etch chemistries and/or etch temperatures may be used. Persons of ordinary skill in the art will understand that various wet etching parameters, such as time, temperature, solution concentration, and others, may be controlled to obtain a desired etch rate to achieve a desired lateral shrinkage amount.

Referring again to FIG. 3A, CNT element 12 is formed above porous dielectric layer 30 by spin-coating a layer of CNT material. CNT material may be formed over porous dielectric layer 30 using any suitable CNT formation process. One technique involves spray- or spin-coating a carbon nanotube suspension over porous dielectric layer 30, thereby creating a random CNT material.

Discussions of various CNT deposition techniques are found in related applications, hereby incorporated by reference herein in their entireties, U.S. patent application Ser. No. 11/968,154, “Memory Cell That Employs A Selectively Fabricated Carbon Nano-Tube Reversible Resistance-Switching Element And Methods Of Forming The Same;” U.S. patent application Ser. No. 11/968,156, “Memory Cell That Employs A Selectively Fabricated Carbon Nano-Tube Reversible Resistance-Switching Element Formed Over A Bottom Conductor And Methods Of Forming The Same;” and U.S. patent application Ser. No. 11/968,159, “Memory Cell With Planarized Carbon Nanotube Layer And Methods Of Forming The Same.”

Any suitable thickness may be employed for the CNT material of CNT element 12. In one embodiment, a CNT material thickness of about 100 to about 1000, and more preferably about 200-500 angstroms, may be used.

Top electrode 28, such as titanium, TiN, tantalum, TaN, tungsten, WN, molybdenum, etc., is formed above CNT element 12. In some embodiments, top electrode 28 may be TiN with a thickness of about 100 to 2000 angstroms, although other materials and/or thicknesses may be used.

Memory cell 10 also includes a sidewall liner 54 formed along the sides of the memory cell layers. Liner 54 may be formed using a dielectric material, such as boron nitride, silicon nitride, silicon oxynitride, low K dielectrics, etc. Example low K dielectrics include carbon doped oxides, silicon carbon layers, or the like.

In some embodiments, the CNT element 12 may be positioned below diode 14.

### Example Fabrication Processes for Memory Cells

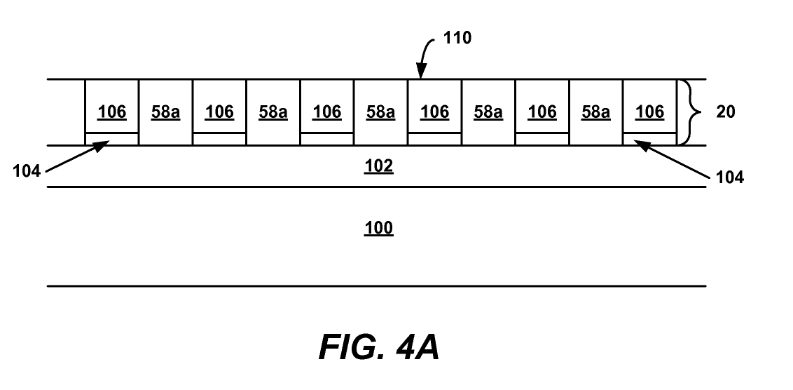

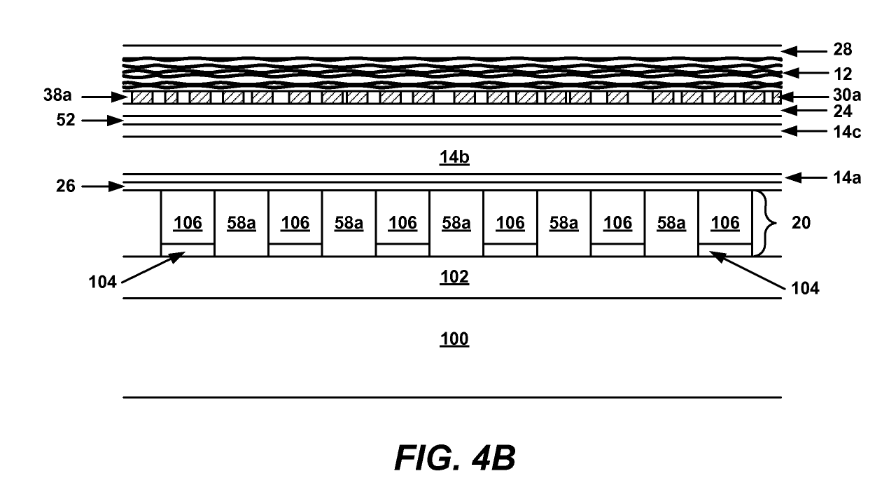

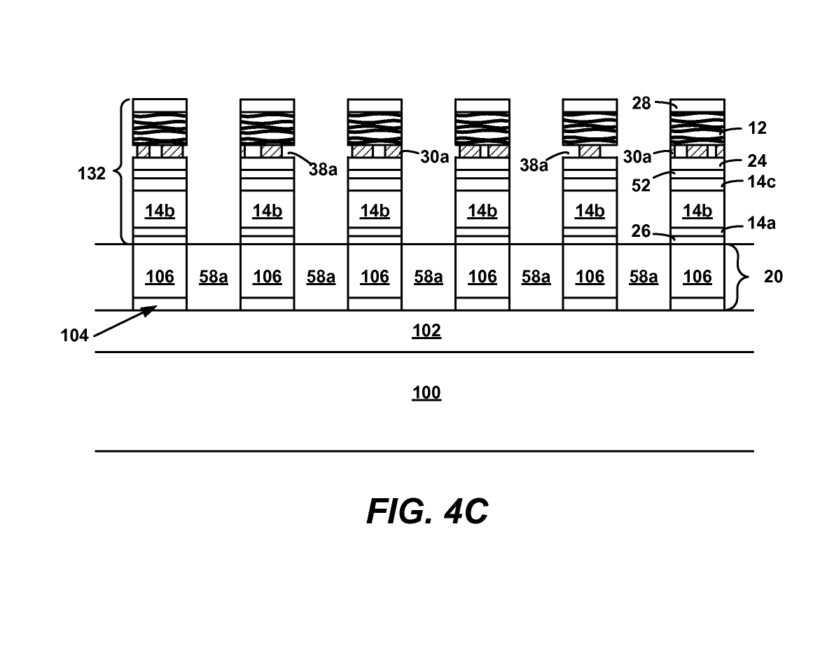

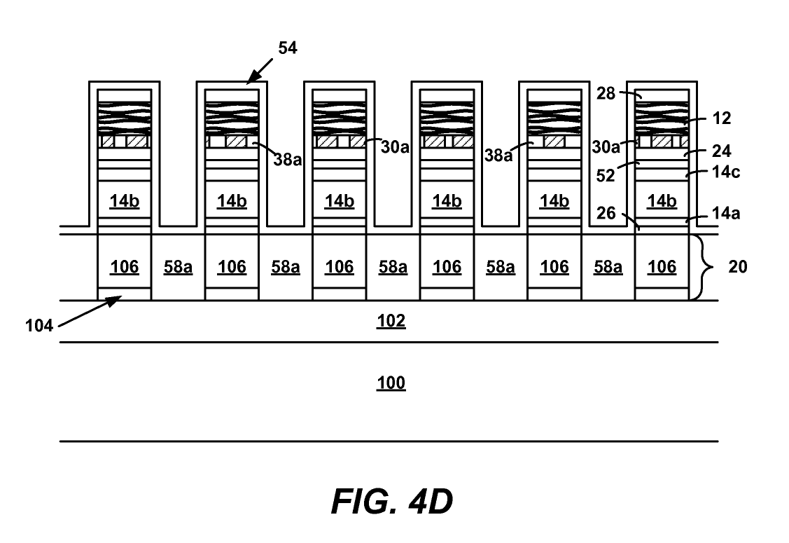

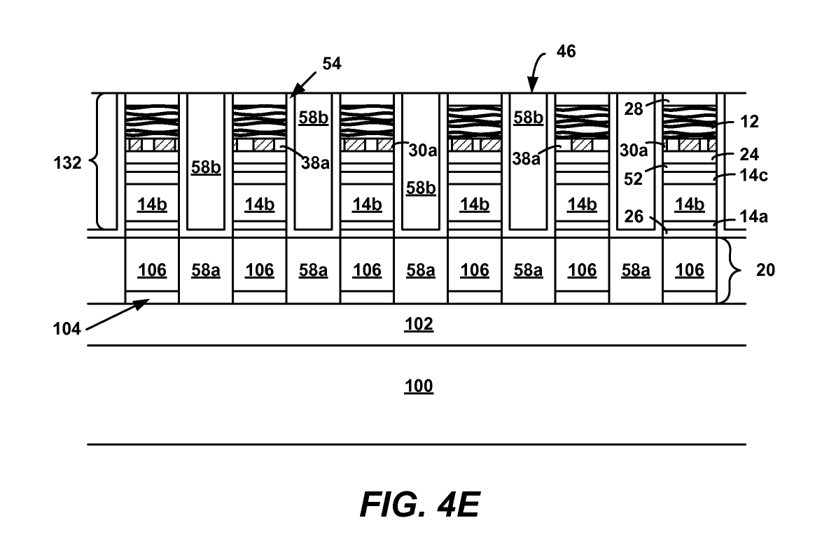

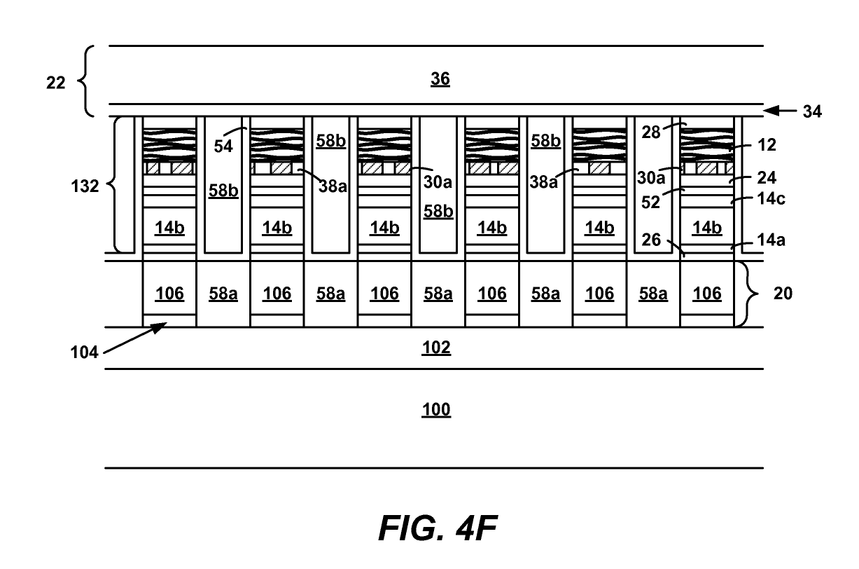

Referring now to FIGS. 4A-4F, a first example method of forming a memory level in accordance with this invention is described. In particular, FIGS. 4A-4F illustrate an example method of forming a memory level including memory cells 10 of FIGS. 3A and 3B. As will be described below, the first memory level includes a plurality of memory cells that each include a steering element and a carbon-based (e.g., CNT) reversible resistance switching element coupled to the steering element. Additional memory levels may be fabricated above the first memory level (as described previously with reference to FIGS. 2C-2D).

With reference to FIG. 4A, substrate 100 is shown as having already undergone several processing steps. Substrate 100 may be any suitable substrate such as a silicon, germanium, silicon-germanium, undoped, doped, bulk, silicon-on-insulator (“SOI”) or other substrate with or without additional circuitry. For example, substrate 100 may include one or more n-well or p-well regions (not shown).

Isolation layer 102 is formed above substrate 100. In some embodiments, isolation layer 102 may be a layer of silicon dioxide, silicon nitride, silicon oxynitride or any other suitable insulating layer.

Following formation of isolation layer 102, an adhesion layer 104 is formed over isolation layer 102 (e.g., by physical vapor deposition or another method). For example, adhesion layer 104 may be about 20 to about 500 angstroms, and preferably about 100 angstroms, of titanium nitride or another suitable adhesion layer such as tantalum nitride, tungsten nitride, tungsten, molybdenum, combinations of one or more adhesion layers, or the like. Other adhesion layer materials and/or thicknesses may be employed. In some embodiments, adhesion layer 104 may be optional.

After formation of adhesion layer 104, a conductive layer 106 is deposited over adhesion layer 104. Conductive layer 106 may include any suitable conductive material such as tungsten or another appropriate metal, heavily doped semiconductor material, a conductive silicide, a conductive silicide-germanide, a conductive germanide, or the like deposited by any suitable method (e.g., CVD, PVD, etc.). In at least one embodiment, conductive layer 106 may comprise about 200 to about 2500 angstroms of tungsten. Other conductive layer materials and/or thicknesses may be used.

Following formation of conductive layer 106, adhesion layer 104 and conductive layer 106 are patterned and etched. For example, adhesion layer 104 and conductive layer 106 may be patterned and etched using conventional lithography techniques, with a soft or hard mask, and wet or dry etch processing. In at least one embodiment, adhesion layer 104 and conductive layer 106 are patterned and etched to form substantially parallel, substantially co-planar first conductors 20. Example widths for first conductors 20 and/or spacings between first conductors 20 range from about 200 to about 2500 angstroms, although other conductor widths and/or spacings may be used.

After first conductors 20 have been formed, a dielectric layer 58a is formed over substrate 100 to fill the voids between first conductors 20. For example, approximately 3000-7000 angstroms of silicon dioxide may be deposited on the substrate 100 and planarized using chemical mechanical polishing or an etchback process to form a planar surface 110. Planar surface 110 includes exposed top surfaces of first conductors 20 separated by dielectric material (as shown). Other dielectric materials such as silicon nitride, silicon oxynitride, low K dielectrics, etc., and/or other dielectric layer thicknesses may be used. Example low K dielectrics include carbon doped oxides, silicon carbon layers, or the like.

In other embodiments of the invention, first conductors 20 may be formed using a damascene process in which dielectric layer 58a is formed, patterned and etched to create openings or voids for first conductors 20. The openings or voids then may be filled with adhesion layer 104 and conductive layer 106 (and/or a conductive seed, conductive fill and/or barrier layer if needed). Adhesion layer 104 and conductive layer 106 then may be planarized to form planar surface 110. In such an embodiment, adhesion layer 104 will line the bottom and sidewalls of each opening or void.

Following planarization, the diode structures of each memory cell are formed. With reference to FIG. 4B, a barrier layer 26 is formed over planarized top surface 110 of substrate 100. In some embodiments, barrier layer 26 may be about 20 to about 500 angstroms, and preferably about 100 angstroms, of titanium nitride or another suitable barrier layer such as tantalum nitride, tungsten nitride, tungsten, molybdenum, combinations of one or more barrier layers, barrier layers in combination with other layers such as titanium/titanium nitride, tantalum/tantalum nitride or tungsten/tungsten nitride stacks, or the like. Other barrier layer materials and/or thicknesses may be employed.

After deposition of barrier layer 26, deposition of the semiconductor material used to form the diode of each memory cell begins (e.g., diode 14 in FIGS. 1 and 3A). Each diode may be a vertical p-n or p-i-n diode as previously described. In some embodiments, each diode is formed from a polycrystalline semiconductor material such as polysilicon, a polycrystalline silicon-germanium alloy, polygermanium or any other suitable material. For convenience, formation of a polysilicon, downward-pointing diode is described herein. It will be understood that other materials and/or diode configurations may be used.

With reference to FIG. 4B, following formation of barrier layer 26, a heavily doped n+ silicon layer 14a is deposited on barrier layer 26. In some embodiments, n+ silicon layer 14a is in an amorphous state as deposited. In other embodiments, n+ silicon layer 14a is in a polycrystalline state as deposited. CVD or another suitable process may be employed to deposit n+ silicon layer 14a. In at least one embodiment, n+ silicon layer 14a may be formed, for example, from about 100 to about 1000 angstroms, preferably about 100 angstroms, of phosphorus or arsenic doped silicon having a doping concentration of about 10²¹ cm⁻³. Other layer thicknesses, doping types and/or doping concentrations may be used. N+ silicon layer 14a may be doped in situ, for example, by flowing a donor gas during deposition. Other doping methods may be used (e.g., implantation).

After deposition of n+ silicon layer 14a, a lightly doped, intrinsic and/or unintentionally doped silicon layer 14b may be formed over n+ silicon layer 14a. In some embodiments, intrinsic silicon layer 14b may be in an amorphous state as deposited. In other embodiments, intrinsic silicon layer 14b may be in a polycrystalline state as deposited. CVD or another suitable deposition method may be employed to deposit intrinsic silicon layer 14b. In at least one embodiment, intrinsic silicon layer 14b may be about 300 to about 4800 angstroms, preferably about 2500 angstroms, in thickness. Other intrinsic layer thicknesses may be used.

A thin (e.g., a few hundred angstroms or less) germanium and/or silicon-germanium alloy layer (not shown) may be formed on n+ silicon layer 14a prior to depositing intrinsic silicon layer 14b to prevent and/or reduce dopant migration from n+ silicon layer 14a into intrinsic silicon layer 14b (as described in the '331 application).

P-type silicon may be either deposited and doped by ion implantation or may be doped in situ during deposition to form a p+ silicon layer 14c. For example, a blanket p+ implant may be employed to implant boron a predetermined depth within intrinsic silicon layer 14b. Example implantable molecular ions include BF₂, BF₃, B and the like. In some embodiments, an implant dose of about 1−5×10¹⁵ ions/cm² may be employed. Other implant species and/or doses may be used. Further, in some embodiments, a diffusion process may be employed. In at least one embodiment, the resultant p+ silicon layer 14c has a thickness of about 100-700 angstroms, although other p+ silicon layer sizes may be used.

Following formation of p+ silicon layer 14c, a silicide-forming metal layer 52 is deposited over p+ silicon layer 14c. Example silicide-forming metals include sputter or otherwise deposited titanium or cobalt. In some embodiments, silicide-forming metal layer 52 has a thickness of about 10 to about 200 angstroms, preferably about 20 to about 50 angstroms and more preferably about 20 angstroms. Other silicide-forming metal layer materials and/or thicknesses may be used. A nitride layer (not shown) may be formed at the top of silicide-forming metal layer 52.

Following formation of silicide-forming metal layer 52, an RTA step may be performed at about 540° C. for about one minute to form silicide layer 50 (FIG. 3A), consuming all or a portion of the silicide-forming metal layer 52. Following the RTA step, any residual nitride layer from silicide-forming metal layer 52 may be stripped using a wet chemistry, as described above. Other annealing conditions may be used.

Following the RTA step and the nitride strip step, bottom electrode 24 is formed above silicide layer 50. Bottom electrode 24 may be titanium, titanium nitride, tantalum, tantalum nitride, tungsten, tungsten nitride, molybdenum, or other similar material. In some embodiments, bottom electrode 24 may be titanium nitride with a thickness of between about 10 to 2000 angstroms, more generally between about 20 to 500 angstroms, although other materials and/or thicknesses may be used. Any suitable method may be used to form bottom electrode 24. For example, CVD, PVD, ALD, plasma enhanced ALD (“PEALD”), or the like may be employed.

Air gap layer 30a is formed above bottom electrode 24. As described above, air gap layer 30a may be Al₂O₃, SiO₂, Si₃N₄, or other similar dielectric material. Air gap layer 30a may have a thickness between about 3 nm to about 5 nm, more generally between about 2 nm to about 10 nm, although other thicknesses may be used. Air gap layer 30a includes pores, holes or openings 38a that may have a diameter of about 10 nm or less, although other sizes may be used.

Air gap layer 30a may be a porous dielectric film, such as a porous aluminum oxide film, which may be formed by depositing a layer of aluminum on bottom electrode 24 (e.g., using ALD), and then performing anodic oxidation, or by using PVD to directly deposit a porous dielectric material, such as the example techniques described above in connection with FIG. 3B. Persons of ordinary skill in the art will understand that other dielectric materials and/or techniques may be used to form porous dielectric film 30a.

CNT element 12 is formed above porous dielectric film 30a. CNT material may be deposited by various techniques. One technique involves spray- or spin-coating a carbon nanotube suspension, thereby creating a random CNT material. Discussions of various CNT deposition techniques are found in previously incorporated U.S. patent application Ser. No. 11/968,154, “Memory Cell That Employs A Selectively Fabricated Carbon Nano-Tube Reversible Resistance-Switching Element And Methods Of Forming The Same;” U.S. patent application Ser. No. 11/968,156, “Memory Cell That Employs A Selectively Fabricated Carbon Nano-Tube Reversible Resistance-Switching Element Formed Over A Bottom Conductor And Methods Of Forming The Same;” and U.S. patent application Ser. No. 11/968,159, “Memory Cell With Planarized Carbon Nanotube Layer And Methods Of Forming The Same.”

Any suitable thickness may be employed for the CNT material of CNT element 12. In one embodiment, a CNT material thickness of about 100 to about 1000, and more preferably about 200-500 angstroms, may be used.

Above CNT element 12, top electrode 28 is formed. Top electrode 28 may be about 20 to about 500 angstroms, and preferably about 100 angstroms, of titanium nitride or another suitable barrier layer such as tantalum nitride, tungsten nitride, tungsten, molybdenum, combinations of one or more barrier layers, barrier layers in combination with other layers such as titanium/titanium nitride, tantalum/tantalum nitride or tungsten/tungsten nitride stacks, or the like. Other barrier layer materials and/or thicknesses may be employed. For example, in some embodiments, the top electrode 28 may be TiN with a thickness of about 100 to 2000 angstroms.

In at least one embodiment, top electrode 28 may be deposited without a pre-clean or pre-sputter step prior to deposition. Example deposition process conditions are as set forth in Table 1.

TABLE 1
EXAMPLE ADHESION/BARRIER LAYER
DEPOSITION PARAMETERS

| | EXAMPLE | PREFERRED |
|---|---|---|
| PROCESS PARAMETER | RANGE | RANGE |
| Argon Flow Rate (sccm) | 20-40 | 20-30 |
| Ar With Dilute H₂ | 0-30 | 0-10 |
| (<10%) Flow Rate (sccm) | | |
| Nitrogen Flow Rate | 50-90 | 60-70 |
| (sccm) | | |
| Pressure (milliTorr) | 1-5000 | 1800-2400 |
| Power (Watts) | 10-9000 | 2000-9000 |
| Power Ramp Rate | 10-5000 | 2000-4000 |
| (Watts/sec) | | |
| Process Temperature (° C.) | 100-600 | 200-350 |
| Deposition Time (sec) | 5-200 | 10-150 |

Other flow rates, pressures, powers, power ramp rates, process temperatures and/or deposition times may be used.

Example deposition chambers include the Endura 2 tool available from Applied Materials, Inc. of Santa Clara, Calif. Other processing tools may be used. In some embodiments, a buffer chamber pressure of about 1-2×10⁻⁷ Torr and a transfer chamber pressure of about 2-5×10⁻⁸ Torr may be used. The deposition chamber may be stabilized for about 250-350 seconds with about 60-80 sccm Ar, 60-70 sccm N₂, and about 5-10 sccm of Ar with dilute H₂ at about 1800-2400 milliTorr. In some embodiments, it may take about 2-5 seconds to strike the target. Other buffer chamber pressures, transfer chamber pressures and/or deposition chamber stabilization parameters may be used.

As shown in FIG. 4C, top electrode 28, CNT element 12, porous dielectric film 30a, bottom electrode 24, silicide-forming metal layer 52, diode layers 14a-14c, and barrier layer 26 are patterned and etched to form pillars 132. Pillars 132 may be formed above corresponding conductors 20 and have substantially the same width as conductors 20, for example, although other widths may be used. Some misalignment may be tolerated. The memory cell layers may be patterned and etched in a single pattern/etch procedure or using separate pattern/etch steps. In at least one embodiment, top electrode 28, CNT element 12, porous dielectric film 30a and bottom electrode 24 are etched together to form MIM stack 32 (FIG. 3A).

For example, photoresist may be deposited, patterned using standard photolithography techniques, layers 26, 14a-14c, 52, 24, 30a, 12 and 28 may be etched, and then the photoresist may be removed. Alternatively, a hard mask of some other material, for example silicon dioxide, may be formed on top of top electrode 28, with bottom antireflective coating (“BARC”) on top, then patterned and etched. Similarly, dielectric antireflective coating (“DARC”) may be used as a hard mask. In some embodiments, one or more additional metal layers may be formed above the CNT element 12 and diode 14 and used as a metal hard mask that remains part of the pillars 132. Use of metal hard masks is described, for example, in U.S. patent application Ser. No. 11/444,936, filed May 13, 2006 and titled “Conductive Hard Mask To Protect Patterned Features During Trench Etch” (hereinafter “the '936 application”) which is hereby incorporated by reference herein in its entirety for all purposes.

Pillars 132 may be formed using any suitable masking and etching process. For example, layers 26, 14a-14c, 52, 24, 30a, 12, and 28 may be patterned with about 1 to about 1.5 micron, more preferably about 1.2 to about 1.4 micron, of photoresist (“PR”) using standard photolithographic techniques. Thinner PR layers may be used with smaller critical dimensions and technology nodes. In some embodiments, an oxide hard mask may be used below the PR layer to improve pattern transfer and protect underlying layers during etching.

In at least some embodiments, a technique for etching CNT material using BCl₃ and Cl₂ chemistries may be employed. For example, U.S. patent application Ser. No. 12/421,803, filed Apr. 10, 2009, titled “Methods For Etching Carbon Nano-Tube Films For Use In Non-Volatile Memories,” which is hereby incorporated by reference herein in its entirety for all purposes, describes techniques for etching CNT material using BCl₃ and Cl₂ chemistries. In other embodiments, a directional, oxygen-based etch may be employed such as is described in U.S. Provisional Patent Application Ser. No. 61/225,487, filed Jul. 14, 2009, which is hereby incorporated by reference herein in its entirety for all purposes. Any other suitable etch chemistries and/or techniques may be used.

In some embodiments, after etching, pillars 132 may be cleaned using a dilute hydrofluoric/sulfuric acid clean. Such cleaning, whether or not PR asking is performed before etching, may be performed in any suitable cleaning tool, such as a Raider tool, available from Semitool of Kalispell, Mont. Example post-etch cleaning may include using ultra-dilute sulfuric acid (e.g., about 1.5-1.8 wt %) for about 60 seconds and/or ultra-dilute hydrofluoric (“HF”) acid (e.g., about 0.4-0.6 wt %) for 60 seconds. Megasonics may or may not be used. Other clean chemistries, times and/or techniques may be employed.

A dielectric liner 54 is deposited conformally over pillars 132, as illustrated in FIG. 4D. In at least one embodiment, dielectric liner 54 may be formed with an oxygen-poor deposition chemistry (e.g., without a high oxygen plasma component) to protect the CNT material of reversible resistance switching element 12 during a subsequent deposition of an oxygen-rich gap-fill dielectric 58b (e.g., SiO₂) (not shown in FIG. 4D). For instance, dielectric sidewall liner 54 may comprise about 200 to about 500 angstroms of silicon nitride. However, the structure optionally may comprise other layer thicknesses and/or other materials, such as SiₓC_{y}N_{z} and SiₓO_{y}N_{z} (with low 0 content), etc., where x, y and z are non-zero numbers resulting in stable compounds. Persons of ordinary skill in the art will understand that other dielectric materials may be used to form dielectric liner 54.

In one example embodiment, a SiN dielectric liner 54 may be formed using the process parameters listed in Table 2. Liner film thickness scales linearly with time. Other powers, temperatures, pressures, thicknesses and/or flow rates may be used.

TABLE 2
PECVD SiN LINER PROCESS PARAMETERS

| | EXAMPLE | PREFERRED |
|---|---|---|
| PROCESS PARAMETER | RANGE | RANGE |
| SiH₄ Flow Rate (sccm) | 0.1-2.0 | 0.4-0.7 |
| NH₃ Flow Rate (sccm) | 2-10 | 3-5 |
| N₂ Flow Rate (sccm) | 0.3-4 | 1.2-1.8 |
| Temperature (° C.) | 300-500 | 350-450 |
| Low Frequency Bias (kW) | 0-1 | 0.4-0.6 |
| High Frequency Bias (kW) | 0-1 | 0.4-0.6 |
| Thickness (Angstroms) | 200-500 | 280-330 |

A dielectric layer 58b is deposited over pillars 132 to fill the voids between pillars 132. For example, approximately 2000-7000 angstroms of silicon dioxide may be deposited and planarized using chemical mechanical polishing or an etchback process to form a planar surface 46, resulting in the structure illustrated in FIG. 4E. Planar surface 46 includes exposed top surfaces of pillars 132 separated by dielectric material 58b (as shown). Other dielectric materials such as silicon nitride, silicon oxynitride, low K dielectrics, etc., and/or other dielectric layer thicknesses may be used.

With reference to FIG. 4F, second conductors 22 may be formed above pillars 132 in a manner similar to the formation of first conductors 20. For example, in some embodiments, one or more barrier layers and/or adhesion layers 34 may be deposited over pillars 132 prior to deposition of a conductive layer 36 used to form second conductors 22.

Conductive layer 36 may be formed from any suitable conductive material such as tungsten, another suitable metal, heavily doped semiconductor material, a conductive silicide, a conductive silicide-germanide, a conductive germanide, or the like deposited by PVD or any other any suitable method (e.g., CVD, etc.). Other conductive layer materials may be used. Barrier layer and/or adhesion layer 34 may include titanium nitride or another suitable layer such as tantalum nitride, tungsten nitride, tungsten, molybdenum, combinations of one or more layers, or any other suitable material(s). The deposited conductive layer 36 and barrier and/or adhesion layer 34 may be patterned and etched to form second conductors 22. In at least one embodiment, second conductors 22 are substantially parallel, substantially coplanar conductors that extend in a different direction than first conductors 20.

In other embodiments of the invention, second conductors 22 may be formed using a damascene process in which a dielectric layer is formed, patterned and etched to create openings or voids for conductors 22. The openings or voids may be filled with adhesion layer 34 and conductive layer 36 (and/or a conductive seed, conductive fill and/or barrier layer if needed). Adhesion layer 34 and conductive layer 36 then may be planarized to form a planar surface.

Following formation of second conductors 22, the resultant structure may be annealed to crystallize the deposited semiconductor material of diodes 14 (and/or to form silicide regions by reaction of the silicide-forming metal layer 52 with p+ region 14c). The lattice spacing of titanium silicide and cobalt silicide are close to that of silicon, and it appears that such silicide layers may serve as “crystallization templates” or “seeds” for adjacent deposited silicon as the deposited silicon crystallizes. Lower resistivity diode material thereby is provided. Similar results may be achieved for silicon-germanium alloy and/or germanium diodes.

Thus in at least one embodiment, a crystallization anneal may be performed for about 10 seconds to about 2 minutes in nitrogen at a temperature of about 600 to 800° C., and more preferably between about 650 and 750° C. Other annealing times, temperatures and/or environments may be used.

Additional memory levels may be similarly formed above the memory level of FIGS. 4A-F. Persons of ordinary skill in the art will understand that alternative memory cells in accordance with this invention may be fabricated with other suitable techniques.

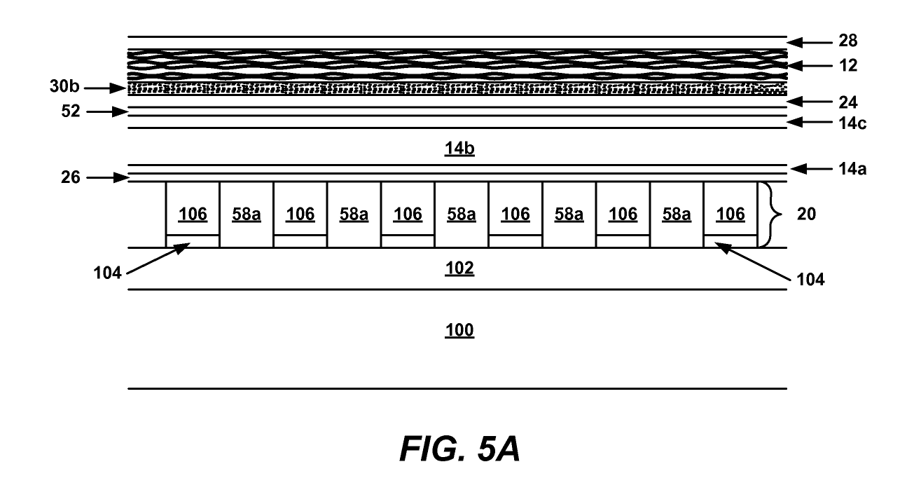

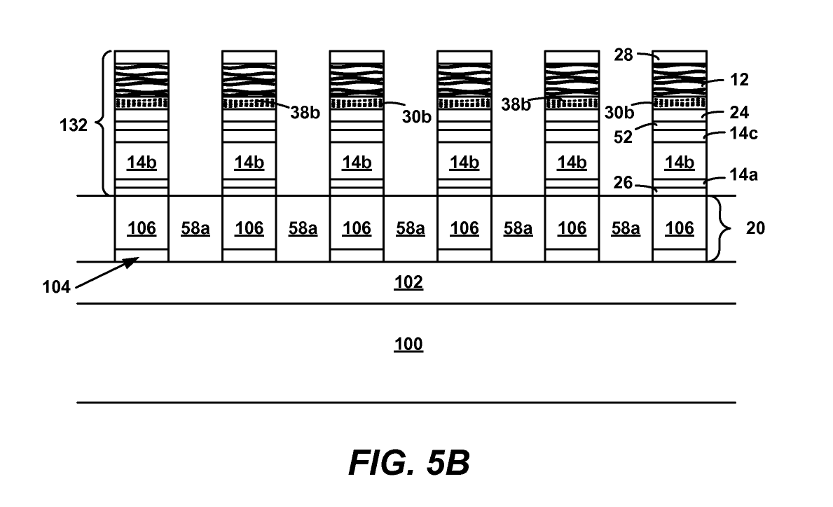

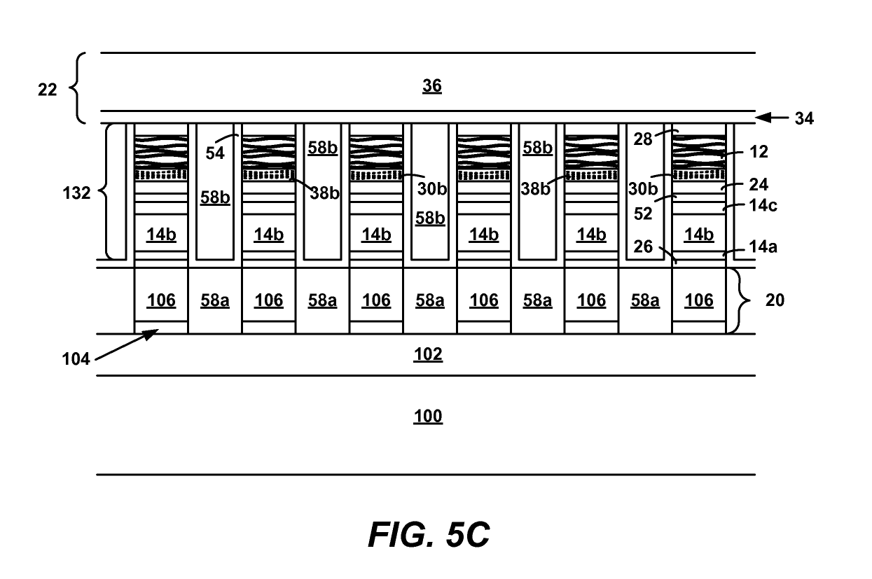

Referring now to FIGS. 5A-5C, a second example method of forming a memory level in accordance with this invention is described. In particular, FIGS. 5A-5C illustrate an example method of forming a memory level including memory cells 10 of FIGS. 3A and 3C.

With reference to FIG. 5A, substrate 100 is shown as having already undergone several processing steps. In particular, the same processing steps described above in connection with FIGS. 4A and 4B have been performed, up to formation of bottom electrode 24.

Air gap layer 30b is formed above bottom electrode 24, and may be a spin-coated dielectric nano-structure, including nano-wires, nano-tubes, and/or nano-particles or other similar nano-structures. For example, air gap layer 30b includes spin-coated dielectric nano-structures 30b having air gaps 38b between dielectric nano-structures. The layer of spin-coated dielectric structures 30b may have a thickness between about 3 nm to about 5 nm, more generally between about 2 nm to about 10 nm, although other thicknesses may be used.

For example, spin-coated dielectric nano-structures 30b may include single-walled, double-walled, or multi-walled BN nanotubes having diameters of between about 1 nm to about 3 nm, more generally between about 0.5 nm to about 5 nm. Alternatively, spin-coated dielectric nano-structures 30b may include nano-wires fabricated from Al₂O₃, SiO₂, Si₃N₄, or other similar dielectric material, having diameters of between about 2 nm to about 5 nm. Other materials, nano-structures and diameters may be used.

Any suitable technique may be used to spin-coat dielectric nano-structures 30b on bottom electrode 24, such as the example techniques described above in connection with FIG. 3C. Persons of ordinary skill in the art will understand that other dielectric materials and/or techniques may be used to form spin-coated dielectric nano-structures 30b.

CNT element 12 and top electrode 28 are formed above spin-coated dielectric nano-structures 30b, such as described above in connection with FIG. 4B. Pillars 132 are formed, such as using the techniques described above in connection with FIG. 4C, resulting in the structure shown in FIG. 5B. A dielectric liner 54 is deposited conformally over pillars 132, a dielectric layer 58b is deposited over pillars 132 to fill the voids between pillars 132, the structure is planarized, and second conductors 22 are formed above pillars 132, such as using the techniques described above in connection with FIGS. 4D-4F, resulting in the structure shown in FIG. 5C.

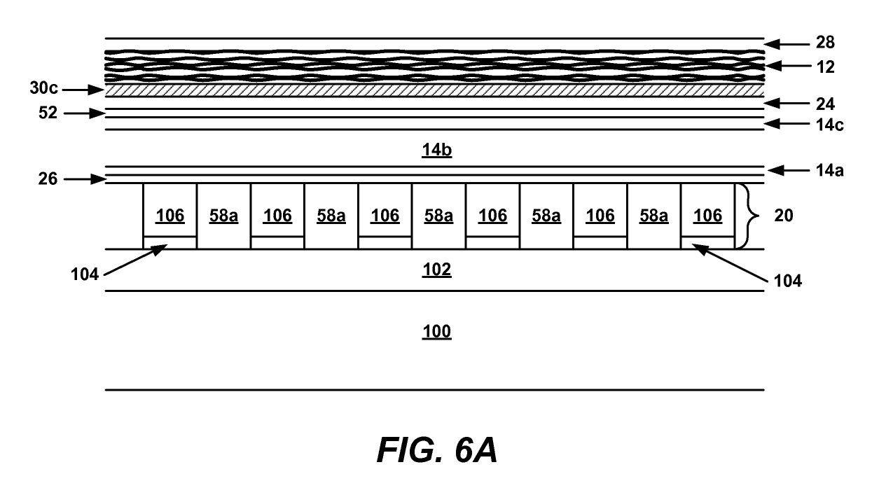

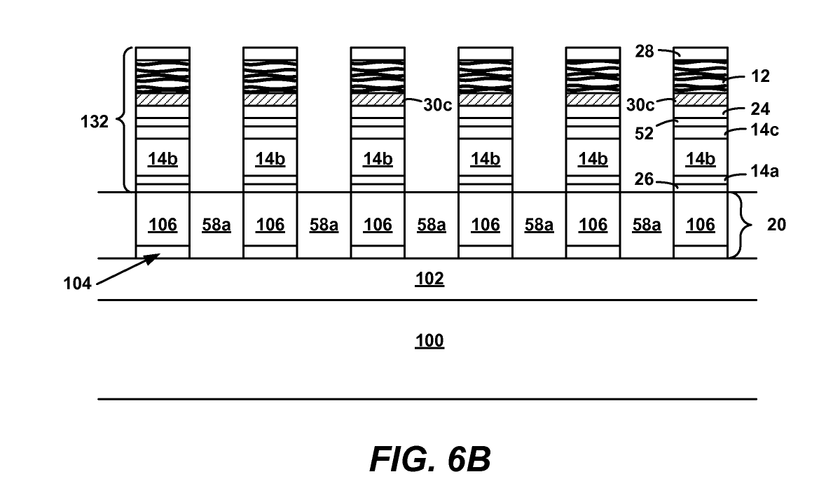

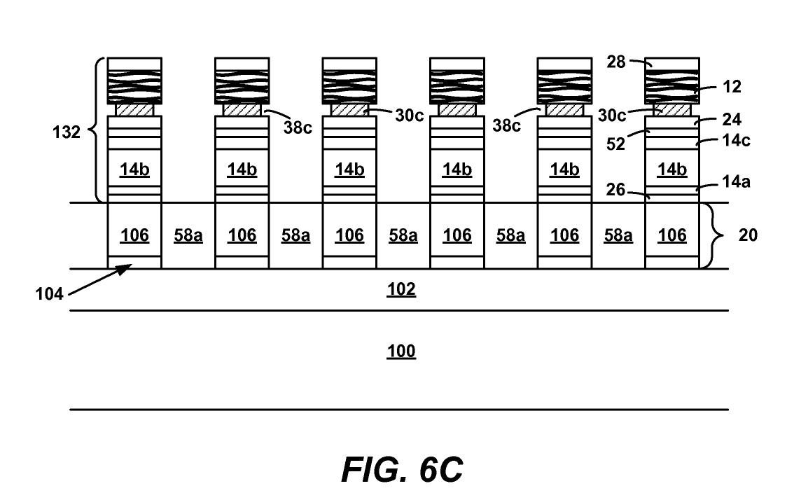

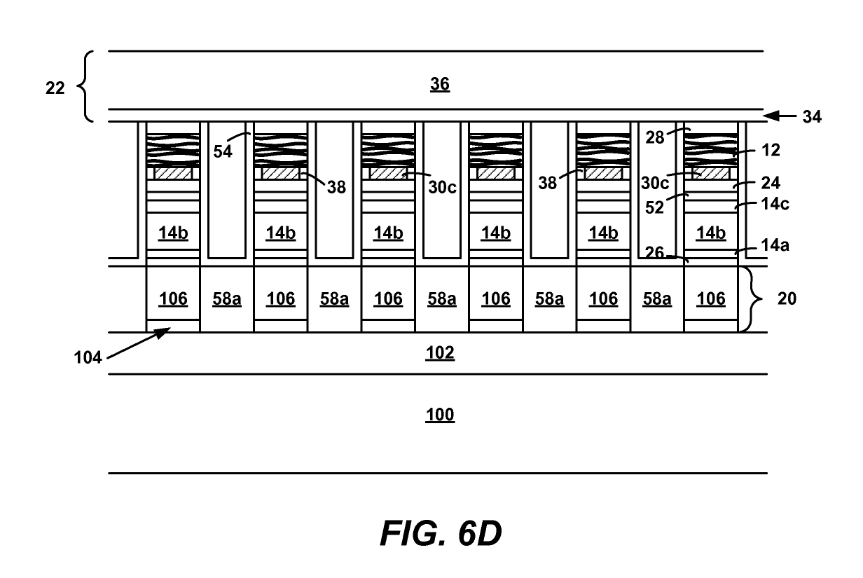

Referring now to FIGS. 6A-6D, another example method of forming a memory level in accordance with this invention is described. In particular, FIGS. 6A-6D illustrate an example method of forming a memory level including memory cells 10 of FIGS. 3A and 3D.

With reference to FIG. 6A, substrate 100 is shown as having already undergone several processing steps. In particular, the same processing steps described above in connection with FIGS. 4A and 4B have been performed, up to formation of bottom electrode 24.

Dielectric film 30c is formed above bottom electrode 24, and may be Al₂O₃, BN, SiO₂, Si₃N₄, or other similar dielectric material. Example deposition techniques include ALD, LPCVD, and IBS, although other techniques may be used. Alternatively, the top surface of bottom electrode 24 may be oxidized to form an insulating oxide layer. Dielectric film 30c may have a thickness between about 3 nm to about 5 nm, more generally between about 2 nm to about 10 nm, although other thicknesses may be used.

CNT element 12 and top electrode 28 are formed above dielectric film 30c, such as described above in connection with FIG. 4B. Pillars 132 are formed, such as using the techniques described above in connection with FIG. 4C, resulting in the structure shown in FIG. 6B.

An etch (e.g., a wet etch or other similar etch) is performed to undercut dielectric film 30c, leaving spaces 38c under CNT element 12, and resulting in the structure shown in FIG. 6C. The etch may laterally shrink dielectric film 30c between about 3 nm to about 5 nm, although other lateral shrinkage amounts may be used.

Any suitable technique may be used to etch dielectric film 30c. For example, for Al₂O₃ and SiO₂ dielectric films, a hydrofluoric acid etch solution may be used. For Si₃N₄ films, phosphoric acid (“H₃PO₄”) at a temperature between about 150° C. to about 180° C. may be used. Other etch chemistries and/or etch temperatures may be used. Persons of ordinary skill in the art will understand that various wet etching parameters, such as time, temperature, solution concentration, and others, may be controlled to obtain a desired etch rate to achieve a desired lateral shrinkage amount.

A dielectric liner 54 is deposited conformally over pillars 132, a dielectric layer 58b is deposited over pillars 132 to fill the voids between pillars 132, the structure is planarized, and second conductors 22 are formed above pillars 132, such as using the techniques described above in connection with FIGS. 4D-4F, resulting in the structure shown in FIG. 6D.

In the embodiment illustrated in FIG. 6D, spaces 38c on shrunken dielectric film 30c form peripheral air gaps 38c that each have an o-ring shape. Persons of ordinary skill in the art will understand that peripheral air gaps 38c may have other shapes.

The foregoing description discloses only example embodiments of the invention. Modifications of the above disclosed apparatus and methods which fall within the scope of the invention will be readily apparent to those of ordinary skill in the art. For instance, in any of the above embodiments, the carbon-based material may be located below diode(s) 14.

Accordingly, although the present invention has been disclosed in connection with example embodiments thereof, it should be understood that other embodiments may fall within the spirit and scope of the invention, as defined by the following claims.

1. A reversible resistance-switching metal-insulator-metal (“MIM”) stack comprising:
a first conducting layer;
a carbon nano-tube (“CNT”) material above the first conducting layer;
a second conducting layer above the CNT material; and
an air gap between the first conducting layer and the CNT material.

2. The reversible resistance-switching MIM stack of claim 1, further comprising a dielectric material between the first conducting layer and the CNT material.

3. The reversible resistance-switching MIM stack of claim 2, wherein the dielectric material comprises the air gap.

4. The reversible resistance-switching MIM stack of claim 2, wherein the dielectric material comprises one or more of a porous dielectric film, a spin-coated dielectric nano-structure, and a shrunken dielectric layer.

5. The reversible resistance-switching MIM stack of claim 2, wherein the dielectric material comprises one or more pores, holes or openings.

6. The reversible resistance-switching MIM stack of claim 2, wherein the dielectric material comprises one or more of aluminum oxide (“Al₂O₃”), boron nitride (“BN”), silicon dioxide (“SiO₂”), silicon nitride (“Si₃N₄”), hafnium oxide (“HfO₂”), tantalum oxide (“Ta₂O₅”), tungsten oxide (“WO₃”), molybdenum trioxide (“MoO₃”), zinc oxide (“ZnO”), titanium oxide (“TiO₂”), and zirconium oxide (“ZrO₂”).

7. The reversible resistance-switching MIM stack of claim 2, wherein the dielectric material has a thickness between about 2 nm to about 10 nm.

8. The reversible resistance-switching MIM stack of claim 2, wherein the dielectric material comprises one or more of single-walled, double-walled, and multi-walled dielectric nanotubes.

9. The reversible resistance-switching MIM stack of claim 2, wherein the dielectric material comprises dielectric nano-wires.

10. The reversible resistance-switching MIM stack of claim 1, wherein the air gap has a diameter of about 10 nm or less.

11. A carbon nano-tube (“CNT”) memory cell comprising:
a first conductor;
a steering element above the first conductor;
a first conducting layer above the first conductor;
a CNT material above the first conducting layer;
a second conducting layer above the CNT material; and
an air gap between the first conducting layer and the CNT material.

12. The CNT memory cell of claim 11, further comprising a dielectric material between the first conducting layer and the CNT material.

13. The CNT memory cell of claim 12, wherein the dielectric material comprises the air gap.

14. The CNT memory cell of claim 12, wherein the dielectric material comprises one or more of a porous dielectric film, a spin-coated dielectric nano-structure, and a shrunken dielectric layer.

15. The CNT memory cell of claim 12, wherein the dielectric material comprises one or more pores, holes or openings.

16. The CNT memory cell of claim 12, wherein the dielectric material comprises one or more of aluminum oxide (“Al₂O₃”), boron nitride (“BN”), silicon dioxide (“SiO₂”), silicon nitride (“Si₃N₄”), hafnium oxide (“HfO₂”), tantalum oxide (“Ta₂O₅”), tungsten oxide (“WO₃”), molybdenum trioxide (“MoO₃”), zinc oxide (“ZnO”), titanium oxide (“TiO₂”), and zirconium oxide (“ZrO₂”).

17. The CNT memory cell of claim 12, wherein the dielectric material has a thickness between about 2 nm to about 10 nm.

18. The CNT memory cell of claim 12, wherein the dielectric material comprises one or more of single-walled, double-walled, and multi-walled dielectric nanotubes.

19. The CNT memory cell of claim 12, wherein the dielectric material comprises dielectric nano-wires.

20. The CNT memory cell of claim 11, wherein the air gap has a diameter of about 10 nm or less.

21. A method of forming a carbon nano-tube (“CNT”) memory cell, the method comprising:
forming a first conductor;
forming a steering element above the first conductor;
forming a first conducting layer above the first conductor;
forming a CNT material above the first conducting layer;
forming a second conducting layer above the CNT material; and
forming an air gap between the first conducting layer and the CNT material.

22. The method of claim 21, further comprising forming a dielectric material between the first conducting layer and the CNT material.

23. The method of claim 22, wherein the dielectric material comprises the air gap.

24. The method of claim 22, wherein the dielectric material comprises one or more of a porous dielectric film, a spin-coated dielectric nano-structure, and a shrunken dielectric layer.

25. The method of claim 22, wherein the dielectric material comprises one or more pores, holes or openings.

26. The method of claim 22, wherein the dielectric material comprises one or more of aluminum oxide (“Al₂O₃”), boron nitride (“BN”), silicon dioxide (“SiO₂”), silicon nitride (“Si₃N₄”), hafnium oxide (“HfO₂”), tantalum oxide (“Ta₂O₅”), tungsten oxide (“WO₃”), molybdenum trioxide (“MoO₃”), zinc oxide (“ZnO”), titanium oxide (“TiO₂”), and zirconium oxide (“ZrO₂”).

27. The method of claim 22, wherein the dielectric material has a thickness between about 2 nm to about 10 nm.

28. The method of claim 22, wherein the dielectric material comprises one or more of single-walled, double-walled, and multi-walled dielectric nanotubes.

29. The method of claim 22, wherein the dielectric material comprises dielectric nano-wires.

30. The method of claim 21, wherein the air gap has a diameter of about 10 nm or less.
